(19) United States
(12) Patent Application Publication
(10) Pub. No.: US 2006/0125030 A1
(43) Pub. Date: Jun. 15, 2006

(54) Hybrid ALD-CVD of PrxOy/ZrO2 films as gate dielectrics

(75) Inventors: Kie Y. Ahn, Chappaqua, NY (US); Leonard Forbes, Corvallis, OR (US)

Correspondence Address: SCHWEGMAN, LUNDBERG, WOESSNER & KLUTH, 121 S. 8TH STREET, SUITE 1600, MINNEAPOLIS, MN, 55402, US

(73) Assignee: Micron Technology, Inc.

(21) Appl. No.: 11/010,766

(22) Filed: Dec. 13, 2004

(51) Int. Cl. H01L 29/78; H01L 21/473

(52) U.S. Cl. 257/411; 438/785; 438/591; 257/635

(57) ABSTRACT

The use of atomic layer deposition (ALD) to form a nanolaminate layered dielectric layer of praseodymium oxide (Pr_{X}O_{Y}) and zirconium oxide (ZrO_{Z}) and a method of fabricating such a combination gate and dielectric layer produces a reliable structure for use in a variety of electronic devices. The nanolaminate layered dielectric structure is formed by depositing praseodymium by atomic layer deposition onto a substrate surface using precursor chemicals, followed by depositing zirconium onto the substrate using precursor chemicals, and repeating to form the thin laminate structure. A nanolaminate layered dielectric layer of praseodymium oxide and zirconium oxide may be used as the gate insulator of a MOSFET, as a capacitor dielectric in a DRAM, as a tunnel gate insulator in flash memories, or a dielectric in NROM devices, because the high dielectric constant (high-k) of the film provides the functionality of a much thinner silicon dioxide film.

### TECHNICAL FIELD

This application relates generally to semiconductor devices and device fabrication and, more particularly, to dielectric layers and their method of fabrication.

### BACKGROUND

The semiconductor device industry has a market driven need to reduce the size of devices such as transistors. To reduce transistor size, the thickness of the silicon dioxide, SiO₂, gate dielectric is reduced in proportion to the shrinkage of the gate length. For example, a metal-oxide-semiconductor field effect transistor (MOSFET) would use a 1.5 mm thick SiO₂ gate dielectric for a gate length of 70 nm. A goal is to fabricate increasingly smaller and more reliable integrated circuits (ICs) for use in products such as processor chips, mobile telephones, and memory devices such as dynamic random access memories (DRAMs).

Currently, the semiconductor industry relies on the ability to reduce or scale the dimensions of its basic devices, primarily, the silicon based MOSFET. This device scaling includes scaling the gate dielectric, which has primarily been fabricated using silicon dioxide. A thermally grown amorphous SiO₂ layer provides an electrically and thermodynamically stable material, where the interface of the SiO₂ layer with underlying silicon provides a high quality interface as well as superior electrical isolation properties. However, increased scaling and other requirements in microelectronic devices have created the need to use other dielectric materials as gate dielectrics.

### SUMMARY

The abovementioned problems are addressed by the present invention and will be understood by reading and studying the following specification. An embodiment for a method for forming an electronic device includes forming a dielectric layer by using an atomic layer deposition (ALD) technique to form a nanolaminate layered dielectric having alternating layers of praseodymium oxide (PrO₂) and zirconium oxide (ZrO₂). The nanolaminate dielectric structure is formed by depositing praseodymium by atomic layer deposition onto a substrate surface using precursor chemicals to form a film of PrO₂ followed by ALD depositing zirconium onto the substrate using precursor chemicals to form ZrO₂ and repeating as often as necessary to form a laminate dielectric structure of the required thickness. A nanolaminate layered dielectric layer of praseodymium oxide (PrO₂) and zirconium oxide (ZrO₂) may be beneficially used because the high dielectric constant (high-k) of the film provides the functionality of a much thinner silicon dioxide film without the reliability loss consequent to using such physically thin films.

Embodiments include structures for capacitors, transistors, memory devices, and electronic systems with dielectric layers containing an atomic layer deposited praseodymium oxide and a zirconium oxide, and methods for forming such structures. These and other aspects, embodiments, advantages, and features will become apparent from the following description and the referenced drawings.

### BRIEF DESCRIPTION OF THE DRAWINGS

FIG. 1 depicts an atomic layer deposition system for fabricating a dielectric layer formed as a nanolaminate layered sequence of praseodymium oxide and zirconium oxide, according to various embodiments of the present invention;

FIG. 2 illustrates a flow diagram of elements for an embodiment of a method to form a dielectric layer containing a nanolaminate layered sequence of praseodymium oxide and zirconium oxide by atomic layer deposition according to various embodiments of the present invention;

FIG. 3 illustrates an embodiment of a configuration of a transistor having a dielectric layer containing an atomic layer deposited nanolaminate layered sequence of praseodymium oxide and zirconium oxide dielectric layer, according to the present invention;

FIG. 4 shows an embodiment of a configuration of a capacitor having a dielectric layer containing an atomic layer deposited nanolaminate layered sequence of praseodymium oxide and zirconium oxide dielectric layer, according to the present invention;

FIG. 5 is a simplified diagram for an embodiment of a controller coupled to an electronic device, according to the present invention; and

FIG. 6 illustrates a diagram for an embodiment of an electronic system having devices with a dielectric film containing an atomic layer deposited nanolaminate layered sequence of praseodymium oxide and zirconium oxide dielectric layer, according to the present invention.

### DETAILED DESCRIPTION

The following detailed description refers to the accompanying drawings that show, by way of illustration, specific aspects and embodiments in which the present invention may be practiced. These embodiments are described in sufficient detail to enable those skilled in the art to practice the present invention. Other embodiments may be utilized and structural, logical, and electrical changes may be made without departing from the scope of the present invention. The various embodiments are not necessarily mutually exclusive, as some embodiments can be combined with one or more other embodiments to form new embodiments.

The terms wafer and substrate used in the following description include any structure having an exposed surface with which to form an integrated circuit (IC) structure. The term substrate is understood to include semiconductor wafers. The term substrate is also used to refer to semiconductor structures during processing, and may include other layers that have been fabricated thereupon. Both wafer and substrate include doped and undoped semiconductors, epitaxial semiconductor layers supported by a base semiconductor or insulator, as well as other semiconductor structures well known to one skilled in the art. The term conductor is understood to generally include n-type and p-type semiconductors and the term insulator or dielectric is defined to include any material that is less electrically conductive than the materials referred to as conductors or as semiconductors.

The term “horizontal” as used in this application is defined as a plane parallel to the conventional plane or surface of a wafer or substrate, regardless of the orientation of the wafer or substrate. The term “vertical” refers to a direction perpendicular to the horizontal as defined above. Prepositions, such as “on”, “side” (as in “sidewall”), “higher”, “lower”, “over” and “under” are defined with respect to the conventional plane or surface being on the top surface of the wafer or substrate, regardless of the orientation of the wafer or substrate. The following detailed description is, therefore, not to be taken in a limiting sense, and the scope of the present invention is defined only by the appended claims, along with the full scope of equivalents to which such claims are entitled.

A gate dielectric in a transistor has both a physical gate dielectric thickness and an equivalent oxide thickness (t_{eq}). The equivalent oxide thickness quantifies the electrical properties, such as capacitance, of the gate dielectric in terms of a representative physical thickness. t_{eq} is defined as the thickness of a theoretical SiO₂ layer that would be required to have the same capacitance density as a given dielectric, ignoring leakage current and reliability considerations.

A SiO₂ layer of thickness, t, deposited on a Si surface as a gate dielectric will have a t_{eq} larger than its thickness, t. This t_{eq} results from the capacitance in the surface channel on which the SiO₂ is deposited due to the formation of a depletion/inversion region. This depletion/inversion region can result in t_{eq} being from 3 to 6 Angstroms (Å) larger than the SiO₂ thickness, t. Thus, with the semiconductor industry driving to someday scale the gate dielectric equivalent oxide thickness to under 10 Å, the physical thickness requirement for a SiO₂ layer used for a gate dielectric would be need to be approximately 4 to 7 Å.

Additional requirements on a SiO₂ layer would depend on the gate electrode used in conjunction with the SiO₂ gate dielectric. Using a conventional polysilicon gate would result in an additional increase in t_{eq} for the SiO₂ layer. This additional thickness could be eliminated by using a metal gate electrode, though metal gates are not currently used in typical complementary metal-oxide-semiconductor field effect transistor (CMOS) technology. Thus, future devices would be designed towards a physical SiO₂ gate dielectric layer of about 5 Å or less. Such a small thickness requirement for a SiO₂ oxide layer creates additional problems.

Silicon dioxide is used as a gate dielectric, in part, due to its electrical isolation properties in a SiO₂—Si based structure. This electrical isolation is due to the relatively large band gap of SiO₂ (8.9 eV) making it a good insulator from electrical conduction. Significant reductions in its band gap would eliminate it as a material for a gate dielectric. As the thickness of a SiO₂ layer decreases, the number of atomic layers, or monolayers of the material in the thickness decreases. At a certain thickness, the number of monolayers will be sufficiently small that the SiO₂ layer will not have a complete arrangement of atoms as in a thicker or bulk layer. As a result of incomplete formation relative to a bulk structure, a thin SiO₂ layer of only one or two monolayers will not form a full band gap. The lack of a full band gap in a SiO₂ gate dielectric may cause an effective short between an underlying conductive silicon channel and an overlying polysilicon gate. This undesirable property sets a limit on the physical thickness to which a SiO₂ layer can be scaled. The minimum thickness due to this monolayer effect is thought to be about 7-8 Å. Therefore, for future devices to have a t_{eq} less than about 10 Å, other dielectrics than SiO₂ need to be considered for use as a gate dielectric.

For a typical dielectric layer used as a gate dielectric, the capacitance is determined as one for a parallel plate capacitance: C=κ∈₀A/t, where κ is the dielectric constant, ∈₀ is the permittivity of free space, A is the area of the capacitor, and t is the thickness of the dielectric. The thickness, t, of a material is related to its t_{eq} for a given capacitance, with SiO₂ having a dielectric constant κₒₓ=3.9, as
t=(κ/κ_{OX})t_{eq}=(κ/3.9)t_{eq}.
Thus, materials with a dielectric constant greater than that of SiO₂, (typically about 3.9), will have a physical thickness that can be considerably larger than a desired t_{eq}, while providing the desired equivalent oxide thickness. For example, an alternate dielectric material with a dielectric constant of 10 could have a thickness of about 25.6 Å to provide a t_{eq} of 10 Å, not including any depletion/inversion layer effects. Thus, a reduced equivalent oxide thickness for transistors can be realized by using dielectric materials with higher dielectric constants than SiO₂.

The thinner equivalent oxide thickness required for lower transistor operating voltages and smaller transistor dimensions may be realized by a significant number of materials, but additional fabricating requirements makes determining a suitable replacement for SiO₂ difficult. The current view for the future of the microelectronics industry still predicts silicon based devices. This requires that the gate dielectric employed be grown on a silicon substrate or silicon layer, which places significant constraints on the substitute dielectric material. During the formation of the dielectric on the silicon layer, there exists the possibility that a small layer of SiO₂ could be formed in addition to the desired dielectric. The result would effectively be a dielectric layer consisting of two sub-layers in parallel with each other and the silicon layer on which the dielectric is formed. In such a case, the resulting capacitance would be that of two dielectrics in series. As a result, the t_{eq} of the dielectric layer would be the sum of the SiO₂ thickness and a multiplicative factor of the thickness, t, of the dielectric being formed, written as
t_{eq}=t_{SiO}_{₂}+(κₒₓ/κ)t.
Thus, if a SiO₂ layer is formed in the process, the t_{eq} is again limited by a SiO₂ layer. In the event that a barrier layer is formed between the silicon layer and the desired dielectric in which the barrier layer prevents the formation of a SiO₂ layer, the t_{eq} would be limited by the layer with the lowest dielectric constant. However, whether a single dielectric layer with a high dielectric constant or a barrier layer with a higher dielectric constant than SiO₂ is employed, the layer directly in contact, or interfacing with the silicon layer must provide a high quality interface to maintain high channel carrier mobility.

One of the advantages of using SiO₂ as a gate dielectric has been that the formation of the SiO₂ layer results in an amorphous gate dielectric. Having an amorphous structure for a gate dielectric provides reduced leakage current problems associated with grain boundaries in polycrystalline gate dielectrics, which may cause high leakage paths. Additionally, grain size and orientation changes throughout a polycrystalline gate dielectric can cause variations in the film's dielectric constant, along with uniformity and surface topography problems. Typically, materials having the advantage of a high dielectric constant relative to SiO₂ also have the disadvantage of a crystalline form, at least in a bulk configuration. The best candidates for replacing SiO₂ as a gate dielectric are those with high dielectric constant, which can be fabricated as a thin layer with an amorphous form.

Candidates to replace SiO₂ include high-K dielectric materials. High-κmaterials include materials having a dielectric constant greater than silicon dioxide, for example, dielectric materials having a dielectric constant greater than about twice the dielectric constant of silicon dioxide. An appropriate high-κ gate dielectric should have a large energy gap (E_{g}) and large energy barrier heights with the silicon substrate for both electrons and holes. Generally, the band gap is inversely related to the dielectric constant for a high-κ material, which lessens some advantages of the high-κ material. A set of high-κ dielectric candidates for replacing silicon oxide as the dielectric material in electronic components in integrated circuit includes the lanthanide oxides such as Pr₂O₃, La₂O₃, Nd₂O₃, Sm₂O₃, Gd₂O₃, Dy₂O₃, Ce₂O₃, Tb₂O₃, Er₂O₃, Eu₂O₃, Lu₂O₃, Tm₂O₃, Ho₂O₃, Pm₂O₃, and Yb₂O₃. Other candidates include various lanthanide silicates and zirconium oxide, ZrO₂. Such high dielectric constant layers provide a significantly thinner equivalent oxide thickness compared with a silicon oxide layer having the same physical thickness. Alternately, such dielectric layers provide a significantly thicker physical thickness than a silicon oxide layer having the same equivalent oxide thickness. This increased physical thickness aids in reducing leakage current.

Another consideration for selecting the material and method for forming a dielectric film for use in electronic devices and systems concerns the roughness of a dielectric film on a substrate. Surface roughness of the dielectric film has a significant effect on the electrical properties of the gate oxide, and the resulting operating characteristics of the transistor. The leakage current through a physical 1.0 nm gate dielectric may increase by a factor of 10 for every 0.1 increase in the root-mean-square (RMS) roughness of the dielectric layer.

During a conventional sputtering deposition process, particles of the material to be deposited bombard the surface at a high energy. When a particle hits the surface, some particles adhere, and other particles cause damage. High energy impacts remove body region particles, creating pits. The surface of such a deposited layer may have a rough contour due to the rough interface at the body region.

In an embodiment, a dielectric film having a substantially smooth surface relative to other processing techniques is formed using atomic layer deposition (ALD). Further, forming such a dielectric film using atomic layer deposition can provide for controlling transitions between material layers. As a result of such control, atomic layer deposited dielectric film may have an engineered transition with a substrate surface, or may be formed with many thin layers of different dielectric materials to enable selection of the dielectric constant to a value between that available from pure dielectric compounds.

ALD, which may be known as atomic layer epitaxy (ALE), is a modification of chemical vapor deposition (CVD) and may also be called “alternatively pulsed-CVD.” In ALD, gaseous precursors are introduced one at a time to the substrate surface mounted within a reaction chamber (or reactor). This introduction of the gaseous precursors takes the form of pulses of each gaseous precursor. In a pulse of a precursor gas, the precursor gas is made to flow into a specific area or region for a short period of time. Between the pulses, the reaction chamber is purged with a gas, which in many cases is an inert gas, and/or evacuated.

In the first reaction step of the ALD process the first precursor saturates and is chemisorbed at the substrate surface, during the first pulsing phase. Subsequent pulsing with a purging gas removes excess precursor from the reaction chamber, specifically the precursor that has not been chemisorbed.

The second pulsing phase introduces a second precursor to the substrate where the growth reaction of the desired film takes place, with a reaction thickness that depends upon the amount of the chemisorbed first precursor. Subsequent to the film growth reaction, reaction byproducts and precursor excess are purged from the reaction chamber. With a precursor chemistry where the precursors adsorb and react with each other on the substrate aggressively, one ALD cycle can be performed in less than one second in properly designed flow type reaction chambers. Typically, precursor pulse times range from about 0.5 sec to about 2 to 3 seconds.

In ALD processes, the saturation of all the reaction and purging phases makes the film growth self-limiting. This self-limiting growth results in large area uniformity and conformality, which has important applications for such cases as planar substrates, deep trenches, and in the processing of porous silicon and high surface area silica and alumina powders. Significantly, ALD provides for controlling film thickness in a straightforward manner by controlling the number of growth cycles.

ALD was originally developed to manufacture luminescent and dielectric films needed in electroluminescent displays. Significant efforts have been made to apply ALD to the growth of doped zinc sulfide and alkaline earth metal sulfide films. Additionally, ALD has been studied for the growth of different epitaxial II-V and II-VI films, nonepitaxial crystalline or amorphous oxide and nitride films and multilayer structures of these. There also has been considerable interest towards the ALD growth of silicon and germanium films, but due to the difficult precursor chemistry, this has not been very successful.

The precursors used in an ALD process may be gaseous, liquid or solid. However, liquid or solid precursors should be volatile. The vapor pressure should be high enough for effective mass transportation. In addition, solid and some liquid precursors may need to be heated inside the reaction chamber and introduced through heated tubes to the substrates. The necessary vapor pressure should be reached at a temperature below the substrate temperature to avoid the condensation of the precursors on the substrate. Due to the self-limiting growth mechanisms of ALD, relatively low vapor pressure solid precursors may be used, though evaporation rates may somewhat vary during the process because of changes in their surface area.

There are several other characteristics for precursors used in ALD. The precursors should be thermally stable at the substrate temperature because their decomposition would destroy the surface control and accordingly the advantages of the ALD method that relies on the reaction of the precursor at the substrate surface. A slight decomposition, if slow compared to the ALD growth, can be tolerated.

The precursors should chemisorb on, or react with the surface, though the interaction between the precursor and the surface as well as the mechanism for the adsorption is different for different precursors. The molecules at the substrate surface should react aggressively with the second precursor, which may be called a reactant, to form the desired solid film. Additionally, precursors should not react with the film to cause etching, and precursors should not dissolve in the film. The use of highly reactive precursors in ALD may contrast with the precursors for conventional metallo-organic CVD (MOCVD) type reactions.

The by-products in the reaction should be gaseous in order to allow their easy removal from the reaction chamber during a purge stage. Further, the by-products should not react or adsorb on the surface.

In a reaction sequence ALD (RS-ALD) process, the self-limiting process sequence involves sequential surface chemical reactions. RS-ALD relies on chemistry between a reactive surface and a reactive molecular precursor. In an RS-ALD process, molecular precursors are pulsed into the ALD reaction chamber separately. The metal precursor reaction at the substrate is typically followed by an inert gas pulse (or purge) to remove excess precursor and by-products from the reaction chamber prior to an input pulse of the next precursor of the fabrication sequence.

By the use of RS-ALD processes, films can be layered in equal metered sequences that are all identical in chemical kinetics, deposition per cycle, composition, and thickness. RS-ALD sequences generally deposit less than a full layer per cycle. Typically, a deposition or growth rate of about 0.25 to about 2.00 Å per RS-ALD cycle can be realized.

The advantages of RS-ALD include continuity at an interface avoiding poorly defined nucleating regions that are typical for thin chemical vapor deposition (<20 Å) and physical vapor deposition (<50 Å), conformality over a variety of substrate topologies due to its layer-by-layer deposition technique, use of low temperature and mildly oxidizing processes, lack of dependence on the reaction chamber, growth thickness dependent solely on the number of cycles performed, and ability to engineer multilayer laminate films with resolution of one to two monolayers. RS-ALD processes allow for deposition control on the order of single monolayers and the ability to deposit monolayers of amorphous films.

A cycle of an ALD deposition sequence includes the pulsing a precursor material, pulsing a purging gas for the precursor, pulsing a reactant precursor, and pulsing the reactant's purging gas, resulting in a very consistent deposition thickness that depends upon the amount of the first precursor that adsorbs onto, and saturates, the surface. This cycle may be repeated until the desired thickness is achieved in a single material dielectric layer, or may be alternated with pulsing a third precursor material, pulsing a purging gas for the third precursor, pulsing a fourth reactant precursor, and pulsing the reactant's purging gas. In the case where the thickness of the first series of cycles results in a dielectric layer that is only a few molecular layers thick, and the second series of cycles also results in a different dielectric layer that is only a few molecular layers thick, this may be known as a nanolayer material or a nanolaminate. A nanolaminate means a composite film of ultra thin layers of two or more different materials in a layered stack, where the layers are alternating layers of the different materials having a thickness on the order of a nanometer, and may be a continuous film only a single monolayer thick of the material. The nanolayers are not limited to alternating single layers of each material, but may include having several layers of one material alternating with a single layer of the other material, to obtain a desired ratio of the two or more materials. Such an arrangement may obtain a dielectric constant that is between the values of the two or more materials singly. A nanolaminate may also include having several layers of one material formed by an ALD reaction either over or under a single layer of a different material formed by another type of reaction, such as a MOCVD reaction.

In an embodiment, a nanolaminate layer of praseodymium oxide is formed on a layer of zirconium oxide, or vice versa, on a substrate mounted in a reaction chamber using RS-ALD. Alternatively, multiple layers may be formed in a repetitive sequence using precursor gases individually pulsed into the reaction chamber. An embodiment includes forming the praseodymium oxide using a metal alkoxy complex precursor gas such as praseodymium 1-methoxy-2-methyl-2-propanolate, having a chemical formula of Pr(OCMe₂CH₂Me)₃. An embodiment includes forming the zirconium oxide using a metal alkoxy complex precursor gas having a chemical formula of Zr(OCMe₂CH₂Me)₄. Other solid or liquid precursors may be used in an appropriately designed reaction chamber. The use of such precursors in an RS-ALD reaction chamber may result in lower deposition temperatures in the range of 350 degrees Celsius, and the ability to use mildly oxidizing reactant materials such as H₂O, H₂O₂, various alcohols, N₂O, ozone or oxygen. Purge gases may include nitrogen, helium, argon or neon. The praseodymium films formed may have the formula of Pr₂O₃, have good thermal and electrical properties, with a high dielectric constant k=31. Such films may survive high temperature anneals (sometimes used to reduce fixed surface state charges and improve metal to semiconductor resistance) of up to 1000 degrees Celsius, and have low leakage currents of less than 5X10⁻⁹ A/cm² with a thickness of 14 Angstroms, with dielectric strengths of 43 MVolts/cm.

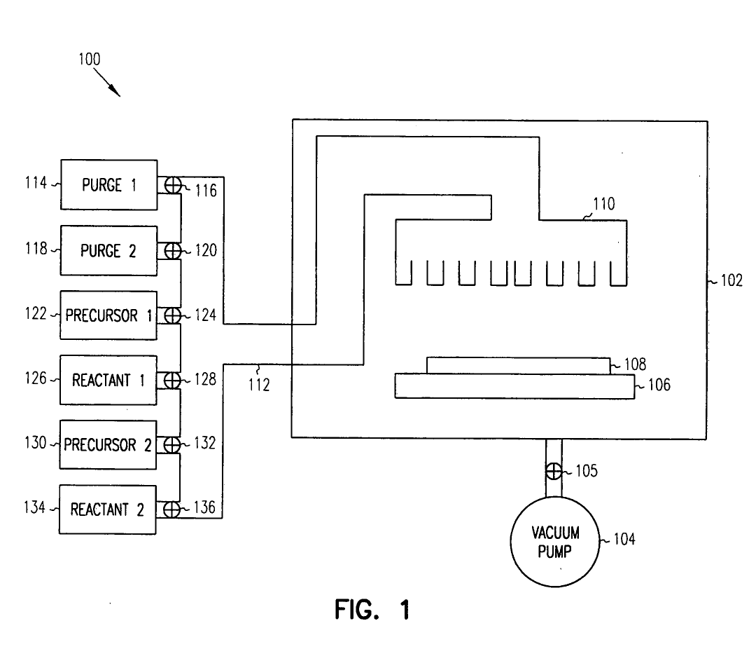

FIG. 1 shows an embodiment of an atomic layer deposition system 100 for forming a nanolaminate dielectric film containing praseodymium oxide alternating with zirconium oxide. The elements depicted permit discussion of the present invention such that those skilled in the art may practice the present invention without undue experimentation. In FIG. 1, a substrate 108 on a heating element/wafer holder 106 is located inside a reaction chamber 102 of ALD system 100. The heating element 106 is thermally coupled to substrate 108 to control the substrate temperature. A gas-distribution fixture 110 introduces precursor, reactant and purge gases to the substrate 108 in a uniform fashion. The gases introduced by the gas distribution fixture, sometimes referred to a showerhead, react with the substrate 108, and any excess gas and reaction products are removed from chamber 102 by vacuum pump 104 through a control valve 105. Each gas originates from individual gas sources 114, 118, 122, 126, 130, and 134, with a flow rate and time controlled by mass-flow controllers 116, 120, 124, 128, 132 and 136, respectively. Gas sources 122 and 126 provide a precursor gas either by storing the precursor as a gas or by providing a location and apparatus for evaporating a solid or liquid material to form the selected precursor gas.

Also included in the system are purging gas sources 114 and 118, coupled to mass-flow controllers 116 and 120, respectively. The embodiment may use only one of the purge gases for all four disclosed illustrative purging steps, or both purge gases may be used simultaneously, or alternately as required for the particular desired result. Furthermore, additional purging gas sources can be constructed in ALD system 100, one purging gas source for each different precursor and reactant gas, for example. For a process that uses the same purging gas for multiple precursor gases fewer purging gas sources may be required for ALD system 100. The precursor, reactant and purge gas sources are coupled by their associated mass-flow controllers to a common gas line or conduit 112, which is coupled to the gas-distribution fixture 110 inside the reaction chamber 102. Gas conduit 112 may also be coupled to another vacuum pump, or exhaust pump, not shown, to remove excess precursor gases, purging gases, and by-product gases at the end of a purging sequence from the gas conduit 112.

Vacuum pump, or exhaust pump, 104 is coupled to chamber 102 by control valve 105, which may be a mass-flow valve, to remove excess precursor gases, purging gases, and by-product gases at the end of a purging sequence from reaction chamber 102. For convenience, control displays, mounting apparatus, temperature sensing devices, substrate maneuvering apparatus, and necessary electrical connections as are known to those skilled in the art are not shown in FIG. 1. Though ALD system 100 is well suited for practicing the present invention, other commercially available ALD systems may also be used.

The use, construction and fundamental operation of reaction chambers for deposition of films are understood by those of ordinary skill in the art of semiconductor fabrication. The present invention may be practiced on a variety of such reaction chambers without undue experimentation. Furthermore, one of ordinary skill in the art will comprehend the necessary detection, measurement, and control techniques in the art of semiconductor fabrication upon reading the disclosure.

The elements of ALD system 100 may be controlled by a computer. To focus on the use of ALD system 100 in the various embodiments of the present invention, the computer is not shown. Those skilled in the art can appreciate that the individual elements such as pressure control, temperature control, and gas flow within ALD system 100 can be under computer control.

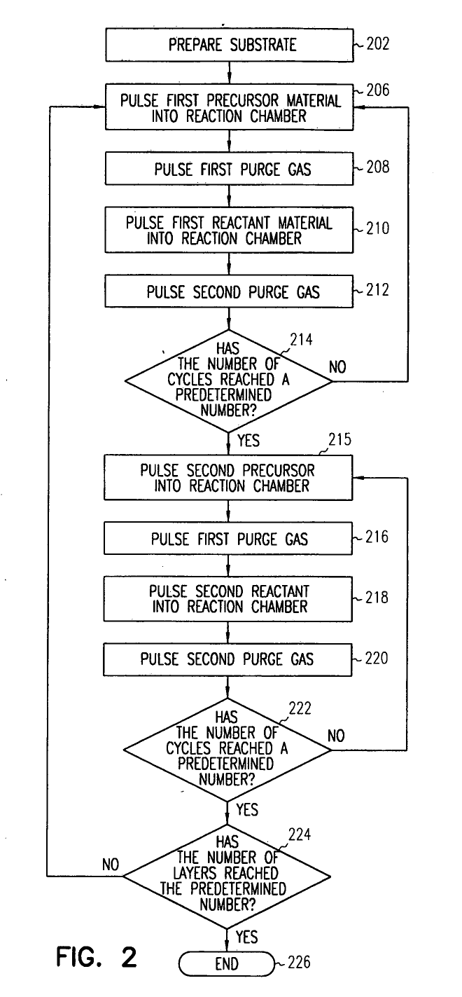

FIG. 2 illustrates a flow diagram of operational steps for an embodiment of a method to form a nanolaminate dielectric layer containing a praseodymium oxide alternating with zirconium oxide layer. Alternatively, there may be a single praseodymium oxide film covered with multiple layers of zirconium oxide films, or vice versa, or multiple films of praseodymium oxide deposited on top of one another, followed by multiple films of zirconium oxide deposited on top of one another, to form a praseodymium oxide film of a desired thickness under a zirconium oxide film of a desired thickness. The single films, whether praseodymium oxide or zirconium oxide, may be deposited by ALD, or by MOCVD. If the single film is deposited by MOCVD, the single film thickness may be larger than that obtainable by a single deposition cycle using an ALD method, and may illustratively be from 50 to 100 Angstroms in thickness. At 202, a substrate is prepared to react immediately with, and chemisorb the first precursor gas. This preparation will remove contaminants such as thin organic films, dirt, and native oxide from the surface of the substrate, and may include a hydrofluoric acid rinse, or a sputter etch in the reaction chamber 102. At 206 a first precursor material enters the reaction chamber for a predetermined length of time, in an embodiment 0.5-2.0 seconds. An embodiment includes the first precursor material being a metal alkoxy complex precursor gas such as praseodymium 1-methoxy-2-methyl-2-propanolate, having a chemical formula of Pr(OCMe₂CH₂Me)₃, but other praseodymium containing materials may also be used. The first precursor material is chemically adsorbed onto the surface of the substrate, the amount depending upon the temperature of the substrate, in one embodiment 350° C., and the presence of sufficient flow of the precursor material. In addition, the pulsing of the precursor may use a pulsing period that provides uniform coverage of an adsorbed monolayer on the substrate surface, or may use a pulsing period that provides partial formation of a monolayer on the substrate surface.

At 208 a first purge gas enters the reaction chamber for a predetermined length of time sufficient to remove substantially all of the non-chemisorbed first precursor material. Typical times may be 1.0-2.0 seconds with a purge gas comprising nitrogen, argon, neon, combinations thereof, or other gases such as hydrogen. At 210 a first reactant gas enters the chamber for a predetermined length of time, sufficient to provide enough of the reactant to chemically combine with the amount of chemisorbed first precursor material on the surface of the substrate. Typical reactant materials include mildly oxidizing materials including but not limited to water vapor, hydrogen peroxide, nitrogen oxides, ozone and oxygen gas, and combinations thereof. Alternatively, if the first dielectric is to be deposited by MOCVD techniques, the first precursor material at 206 is mixed with the first reactant gas at 210, with or without the purge gas 208, for a time period sufficient to form a layer of the desired thickness. At 212 a second purge gas, which may be the same or different from the first purge gas, enters the chamber for a predetermined length of time, sufficient to remove substantially all non-reacted materials and any reaction byproducts from the chamber.

At 214 a decision is made as to whether or not the thickness of the first dielectric material in the dielectric has reached the desired thickness, or whether another deposition cycle is required. If another deposition cycle is needed, then the operation returns to 206, until the desired first dielectric layer is completed, at which time the process moves on to the deposition of the second material at 215. At 215 a second precursor material enters the reaction chamber for a predetermined length of time, in an embodiment 0.5-2.0 seconds. An embodiment includes the first precursor material being a metal alkoxy complex precursor gas such as zirconium 1-methoxy-2-methyl-2-propanolate, having a chemical formula of Zr(OCMe₂CH₂Me)₄, but other zirconium containing materials may also be used. The second precursor material is chemically adsorbed onto the surface of the substrate, in this case being the top surface of the first dielectric material, the amount of absorption depending upon the temperature of the substrate, in one embodiment 350° C., and the presence of sufficient flow of the precursor material. In addition, the pulsing of the precursor may use a pulsing period that provides uniform coverage of an adsorbed monolayer on the substrate surface, or may use a pulsing period that provides partial formation of a monolayer on the substrate surface.

At 216 the first purge gas is shown as entering the chamber, but the invention is not so limited. The purge gas used in the second dielectric material deposition may be the same or different from either of the two previously noted purge gases, and FIG. 1 could be shown as having more than the two purge gases shown. The purge cycle continues for a predetermined length of time sufficient to remove substantially all of the non-chemisorbed second precursor material.

At 218 a second reactant gas, which may the same or different from the first reactant gas, enters the chamber for a predetermined length of time, sufficient to provide enough of the reactant to chemically combine with the amount of chemisorbed second precursor material on the surface of the substrate. At 220 another purge gas enters the chamber, which may be the same or different from any of the three previously discussed purge gases, for a predetermined length of time, sufficient to remove substantially all non-reacted materials and any reaction byproducts from the chamber.

At 222 a decision is made as to whether or not the thickness of the second dielectric material in the nanolaminate dielectric has reached the desired thickness, or whether another deposition cycle is required. If another deposition cycle is needed, then the operation returns to 214, until the desired second dielectric layer is completed. The desired thicknesses of the first and second dielectric materials in the nanolaminate dielectric may not be the same thickness, and there may be more deposition cycles for one dielectric material as compared to the other. If the second dielectric layer has reached the desired thickness, the process moves on to a decision at 224 of whether the number of layers of the first and second dielectric materials has reached the desired number. In this illustrative embodiment a single layer of the first dielectric and a single layer of the second dielectric have been completed at this point in the process. If more than a single layer of each dielectric material is desired, the process moves back to another deposition of the first dielectric material at 206. After the number of interleaved layers of dielectrics one and two has reached the desired value, the deposition ends at 226. Because the dielectric values of the RS-ALD oxides in the described embodiment are high, for example praseodymium oxide may have a dielectric constant of 31, and because the highly controlled layer thickness may be a single monolayer for each one of the interleaved dielectric layers, the physical thickness needed to obtain the equivalent dielectric properties of a very thin silicon dioxide layer may require that there be from two to ten layers of each of the two dielectric materials described in the embodiments.

The embodiments described herein provide a process for growing a dielectric film having a wide range of useful equivalent oxide thickness, t_{eq}, associated with a dielectric constant in the range from about 11 to about 30. This range of dielectric constants provides for a t_{eq} ranging from about 13% to about 36% relative to a given silicon dioxide thickness. In an embodiment, a dielectric layer containing a lanthanide oxide layer has a t_{eq} ranging from about 5 Å to about 20 Å. In an embodiment, a dielectric layer containing a lanthanide oxide layer has a t_{eq} of less than 5 Å. Alternately, for an acceptable silicon dioxide thickness, an embodiment for a lanthanide oxide may be from less than three to less than eight larger than the acceptable silicon dioxide thickness providing enhanced probability for reducing leakage current. Further, dielectric films of lanthanide oxide layer formed by atomic layer deposition can provide not only thin t_{eq} films, but also films with relatively low leakage current. Additionally, the novel process can be implemented to form transistors, capacitors, memory devices, and other electronic systems including information handling devices. The invention is not limited to two dielectric materials, and the equipment described in FIG. 1 could have included a precursor and reactant 3, 4, which are not described for simplicity.

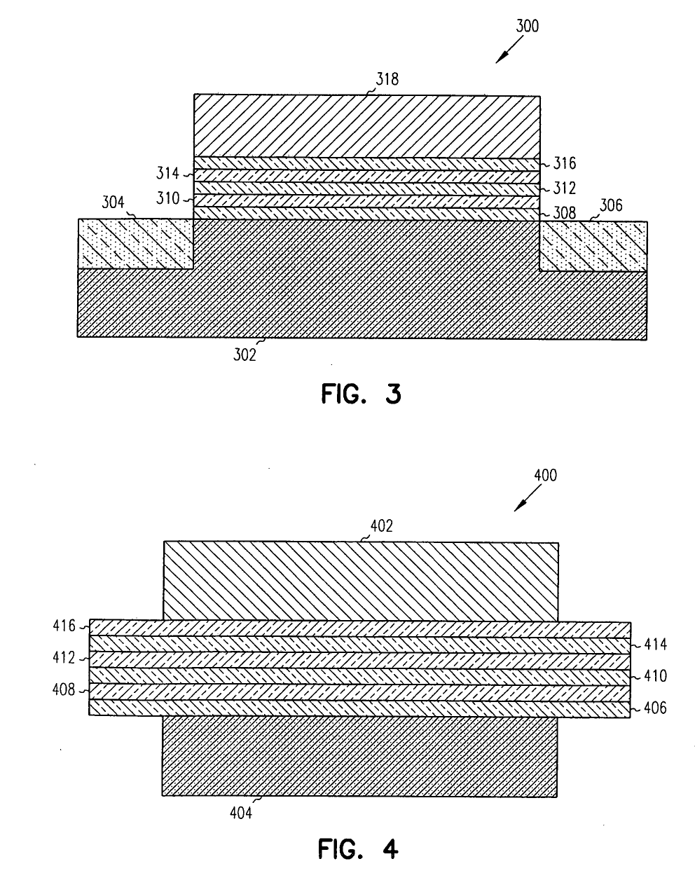

FIG. 3 illustrates a single transistor in an embodiment of a method to form a dielectric layer containing an RS-ALD deposited nanolaminate gate oxide layer. This embodiment may be implemented with the system 100 of FIG. 1 used as an atomic layer deposition, or by using the system 100 as a MOCVD system for one of the two different materials, or a combination thereof. A substrate 302 is prepared, typically a silicon or silicon containing material. In other embodiments, germanium, gallium arsenide, silicon-on-sapphire substrates, or other suitable substrates may also be used. The preparation process includes cleaning substrate 302 and forming various layers and regions of the substrate, such as drain diffusion 304 and source diffusion 306 of an illustrative metal oxide semiconductor (MOS) transistor 300, prior to forming a gate dielectric. In an embodiment, the substrate is cleaned to provide an initial substrate depleted of its native oxide. In an embodiment, the initial substrate is cleaned to provide a hydrogen-terminated surface. In an embodiment, a silicon substrate undergoes a final hydrofluoric (HF) rinse prior to ALD processing to provide the silicon substrate with a hydrogen-terminated surface without a native silicon oxide layer. Cleaning immediately preceding atomic layer deposition aids in reducing an occurrence of silicon oxide as an interface between silicon based substrate and dielectric formed using the atomic layer deposition process. The sequencing of the formation of the regions of the transistor being processed may follow the generally understood fabrication of a MOS transistor as is well known to those skilled in the art.

The dielectric covering the area on the substrate 302 between the source and drain diffused regions 304 and 306 may deposited by RS-ALD in this illustrative embodiment, or it may be partially deposited by MOCVD, and may comprise one or more praseodymium oxide layers 308, 312, and 316, having interleaved zirconium oxide layers, 310 and 314. Alternatively, there may be a single praseodymium oxide layer 308, followed by zirconium oxide layers 310-314, or other combinations of interleaved and non-interleaved layers of varying thickness and deposition method. This nanolaminate dielectric layer is referred to as the gate oxide. In this illustrative embodiment the praseodymium oxide layer 308 is shown as being the first layer and in direct contact with the substrate 302; the invention however, is not so limited. There may be a diffusion barrier layer inserted between the first dielectric layer 308 and the substrate 302 to prevent metal contamination from affecting the electrical properties of the device. The described embodiment may also include having the first dielectric layer as zirconium oxide, since this affects the surface states and the work function of the nanolaminate dielectric layer. The illustrative embodiment also shows the two different dielectric layers having the same thickness, however the desired dielectric properties of the nanolaminate film may be best achieved by adjusting the ratio of the thickness of the two dielectric materials to different values. The transistor 300 has a conductive material forming a gate 318 in this illustrative embodiment, but the nanolaminate dielectric may also be used in a floating gate device such as an EEPROM transistor, as either one or both of the floating gate and the control gate oxide layers.

In an illustrative embodiment, gate dielectric (layers 308-316) include a tunnel gate insulator and a floating gate dielectric in a flash memory device. Use of dielectric layers containing a nanolaminate atomic layer deposited dielectric layer for a gate dielectric and/or floating gate dielectric in which the dielectric layer contacts a conductive layer is not limited to silicon based substrates, but may be used with a variety of semiconductor substrates.

The embodiments of methods for forming dielectric layers containing a RS-ALD deposited dielectric layer contacting a conductive layer may also be applied to forming capacitors in various integrated circuits, memory devices, and electronic systems. In an embodiment including a capacitor 400 illustrated in FIG. 4, a method includes forming a first conductive layer 402, a second conductive layer 404, having a nanolaminate dielectric having interleaved layers 406-416 of two different dielectric materials, formed between the two conductive layers. The conductive layers 402 and 404 may include metals, doped polysilicon, silicided metals, polycides, or conductive organic compounds, without affecting the teachings of this embodiment. The sequencing of the layers depends on the application and may include a single layer of each material, one layer of one of the materials and multiple layers of the other, or other combinations of layers including different layer thicknesses. The effective dielectric constant associated with a nanolaminate structure is attributable to N capacitors in series, where each capacitor has a thickness defined by the thickness of the corresponding layer. By selecting each thickness and the composition of each layer, a nanolaminate structure can be engineered to have a predetermined dielectric constant. Structures such as the nanolaminate structure shown in FIGS. 3 and 4 may be used in NROM flash memory devices as well as other integrated circuits. Transistors, capacitors, and other devices having dielectric films may be implemented into memory devices and electronic systems including information handling devices. Embodiments of these information handling devices include wireless systems, telecommunication systems, computers and integrated circuits.

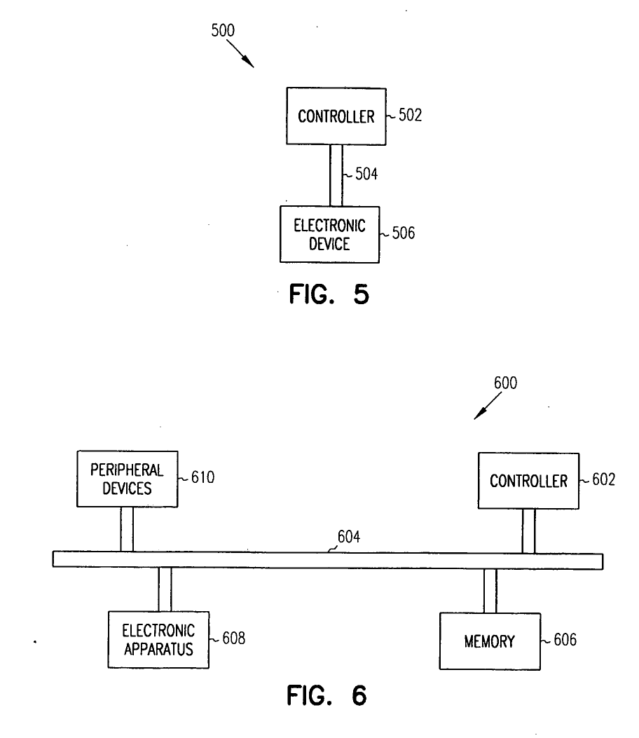

FIG. 5 illustrates a diagram for an electronic system 500 having one or more devices having a dielectric layer containing an atomic layer deposited oxide layer formed according to various embodiments of the present invention. Electronic system 500 includes a controller 502, a bus 504, and an electronic device 506, where bus 504 provides electrical conductivity between controller 502 and electronic device 506. In various embodiments, controller 502 and/or electronic device 506 include an embodiment for a dielectric layer containing a nanolaminate RS-ALD deposited oxide layer as previously discussed herein. Electronic system 500 may include, but is not limited to, information handling devices, wireless systems, telecommunication systems, fiber optic systems, electro-optic systems, and computers.

FIG. 6 depicts a diagram of an embodiment of a system 600 having a controller 602 and a memory 606. Controller 602 and/or memory 606 includes a dielectric layer having a nanolaminate RS-ALD dielectric layer. System 600 also includes an electronic apparatus 608, and a bus 604, where bus 604 may provide electrical conductivity and data transmission between controller 602 and electronic apparatus 608, and between controller 602 and memory 606. Bus 604 may include an address, a data bus, and a control bus, each independently configured. Bus 604 also uses common conductive lines for providing address, data, and/or control, the use of which may be regulated by controller 602. In an embodiment, electronic apparatus 608 includes additional memory devices configured similarly to memory 606. An embodiment includes an additional peripheral device or devices 610 coupled to bus 604. In an embodiment controller 602 is a processor. Any of controller 602, memory 606, bus 604, electronic apparatus 608, and peripheral device or devices 610 may include a dielectric layer having a nanolaminate RS-ALD deposited oxide layer in accordance with the disclosed embodiments.

System 600 may include, but is not limited to, information handling devices, telecommunication systems, and computers. Peripheral devices 610 may include displays, additional storage memory, or other control devices that may operate in conjunction with controller 602 and/or memory 606. It will be understood that embodiments are equally applicable to any size and type of memory circuit and are not intended to be limited to a particular type of memory device. Memory types include a DRAM, SRAM (Static Random Access Memory) or Flash memories. Additionally, the DRAM could be a synchronous DRAM commonly referred to as SGRAM (Synchronous Graphics Random Access Memory), SDRAM (Synchronous Dynamic Random Access Memory), SDRAM II, and DDR SDRAM (Double Data Rate SDRAM), as well as Synchlink or Rambus DRAMs and other emerging DRAM technologies.

Formation of nanolaminate praseodymium oxide/zirconium oxide layers by a nanolaminate RS-ALD deposition may be realized using a Zr(OCMe₂CH₂Me)₄ precursor and a Pr(OCMe₂CH₂Me)₃ precursor. Further, nanolaminate praseodymium oxide/zirconium oxide films formed by RS-ALD processed in relatively low temperatures, such as 350° C., may be amorphous and possess smooth surfaces. Such RS-ALD oxide films may provide enhanced electrical properties as compared to physical deposition methods, such as sputtering, or typical chemical layer depositions, due to their smoother surface, and reduced damage, resulting in reduced leakage current. Additionally, such dielectric layers provide a significantly thicker physical thickness than a silicon oxide layer having the same equivalent oxide thickness, where the increased thickness may also reduce leakage current issues. These properties of layers containing nanolaminate praseodymium oxide/zirconium oxide films allow for application as dielectric layers in numerous electronic devices and systems.

Praseodymium oxides include materials having the formulas Pr₆O₁₁, Pr₂O₃, PrO₃, and PrO₂, and combinations thereof, and zirconium oxide includes materials having formulas ZrO, and ZrO₂, and combinations thereof. The conductive layers contacting the nanolaminate may include metals, semiconductor materials, polycrystalline semiconductor materials and doped materials of either conductivity type.

Capacitors, transistors, higher level ICs or devices including memory devices, and electronic systems are constructed utilizing the novel process for forming a dielectric film having an ultra thin equivalent oxide thickness, t_{eq}. Gate dielectric layers or films containing atomic layer deposited lanthanide oxide are formed having a dielectric constant (κ) substantially higher than that of silicon oxide, such that these dielectric films are capable of a t_{eq} thinner than SiO₂ gate dielectrics of the same physical thickness. Alternately, the high dielectric constant relative to silicon dioxide allows the use of much larger physical thickness of these high-κ dielectric materials for the same t_{eq} of SiO₂. Forming the relatively larger thickness aids in processing gate dielectrics and other dielectric layers in electronic devices and systems.

Although specific embodiments have been illustrated and described herein, it will be appreciated by those of ordinary skill in the art that any arrangement that is calculated to achieve the same purpose may be substituted for the specific embodiments shown. This application is intended to cover any adaptations or variations of embodiments of the present invention. It is to be understood that the above description is intended to be illustrative, and not restrictive, and that the phraseology or terminology employed herein is for the purpose of description and not of limitation. Combinations of the above embodiments and other embodiments will be apparent to those of skill in the art upon studying the above description. The scope of the present invention includes any other applications in which embodiments of the above structures and fabrication methods are used. The scope of the embodiments of the present invention should be determined with reference to the appended claims, along with the full scope of equivalents to which such claims are entitled.

What is claimed is:

1. A method comprising:
forming a dielectric layer on a substrate containing at least one praseodymium oxide layer and at least one zirconium oxide layer by at least one of a reaction sequence atomic layer deposition and a metallo-organic chemical vapor deposition; and
forming a metal layer on the dielectric layer.

2. The method of claim 1, wherein forming the praseodymium oxide layer includes forming an amorphous oxide including Pr₆O₁₁, Pr₂O₃, PrO₃, and PrO₂, and combinations thereof.

3. The method of claim 1, wherein forming the zirconium oxide layer includes forming an amorphous oxide including ZrO, and ZrO₂, and combinations thereof.

4. The method of claim 1, wherein the dielectric layer includes at least four alternating praseodymium oxide layers and zirconium oxide layers.

5. The method of claim 1, wherein the substrate includes a conductive layer disposed below the dielectric layer.

6. The method of claim 5, wherein the method is a method of forming a capacitive device.

7. The method of claim 1, wherein the substrate includes at least two diffused regions having a first conductivity type, separated by a region of a second conductivity type disposed below the dielectric layer and metal layer.

8. The method of claim 7, wherein the method is a method of forming a transistor device.

9. The method of claim 7, wherein the method is a method of forming a memory device.

10. The method of claim 1, wherein each individual one of the praseodymium oxide layers is less than or equal to two monolayers in thickness.

11. The method of claim 10, wherein each individual one of the praseodymium oxide layers is a continuous monolayer.

12. The method of claim 1, wherein the dielectric layer has a root mean square surface roughness that is less than one tenth of the layer thickness.

13. The method of claim 1, wherein the thickness of the praseodymium oxide layer and the zirconium oxide layer is selected to result in a dielectric constant of the dielectric film of greater than 30.

14. The method of claim 1, wherein the dielectric film is separated from the substrate by a diffusion barrier.

15. The method of claim 1, wherein the dielectric film is formed at a temperature of less than 350° C.

16. The method of claim 1, wherein the dielectric film is formed using a precursor material comprising a formula Pr(OCMe₂CH₂Me)₃.

17. The method of claim 1, wherein the dielectric layer is formed by exposing an activated substrate surface at a preselected temperature to a first precursor material for a preselected first time period and a preselected flow volume of the first precursor material to saturate the substrate surface with the first precursor material;
exposing the substrate surface to a preselected volume of a first purge material for a preselected second time period to remove substantially all of a non-adsorbed portion of the first precursor material from the substrate surface;
exposing the substrate surface to a preselected volume of a first reactant material for a preselected third time period to react with the adsorbed portion of the first precursor material on the substrate surface to form a first dielectric material having a first intermediate thickness to complete a first deposition cycle;
exposing the substrate surface to a preselected volume of a second purge material for a preselected fourth time period to remove substantially all of a non-reacted portion of the first reactant material, and a first plurality of gaseous reaction byproducts from the substrate surface;
repeating the first deposition cycle until a preselected final first dielectric material thickness is obtained;
exposing the substrate surface to a second precursor material for a preselected fifth time period and a preselected flow volume of the second precursor material to saturate the substrate surface with the second precursor material;
exposing the substrate surface to a preselected volume of a third purge material for a preselected sixth time period to remove substantially all of a non-adsorbed portion of the second precursor material from the substrate surface;
exposing the substrate surface to a preselected volume of a second reactant material for a preselected seventh time period to react with the adsorbed portion of the second precursor material on the substrate surface to form a second dielectric material having a second intermediate thickness to complete a second deposition cycle;
exposing the substrate surface to a preselected volume of a fourth purge material for a preselected eighth time period to remove substantially all of a non-reacted portion of the second reactant material, and a second plurality of gaseous reaction byproducts from the substrate surface; and
repeating the second deposition cycle until a preselected final second dielectric material thickness is obtained.

18. The method of claim 17, wherein the process of forming the final first dielectric film thickness and the final second dielectric thickness is repeated to form multiple interleaved layers of the first and second dielectric films having a preselected overall dielectric film thickness and dielectric constant.

19. The method of claim 18, wherein the first dielectric film comprises praseodymium oxide.

20. The method of claim 19, wherein the praseodymium oxide film is a continuous monolayer having a surface roughness of less than 0.1 of the first thickness.

21. A method comprising:
forming an integrated circuit having a dielectric layer containing at least one praseodymium oxide layer and at least one zirconium oxide layer by at least one of reaction sequence atomic layer deposition and a metallo-organic chemical vapor deposition; and
forming a conductive layer on the dielectric layer.

22. The method of claim 21, wherein the conductive layer comprises a metal.

23. The method of claim 22, wherein the method further includes:
forming metallization lines in the metal layer to electrically connect to a device in the integrated circuit; and
annealing the device in a H₂ ambient after forming the metallization lines.

24. The method of claim 21, wherein the method includes forming the dielectric layer as a gate insulator having a portion of the metal layer as a gate of a transistor in the integrated circuit.

25. The method of claim 24, wherein the method includes forming the dielectric layer as a gate insulator in a CMOS transistor in the integrated circuit.

26. The method of claim 24, wherein the method includes forming the metal layer as an electrode of a capacitor and forming the dielectric layer as a dielectric of the capacitor.

27. The method of claim 21, wherein the method further includes forming a plurality of interleaved dielectric layers of praseodymium oxide and zirconium oxide layers to form a nanolaminate gate dielectric.

28. The method of claim 27, wherein a first one of the interleaved dielectric layers comprises praseodymium oxide.

29. The method of claim 21, wherein the dielectric layer is formed at a temperature of less than 350° C.

30. The method of claim 21, wherein the dielectric layer is formed using a precursor material comprising a formula Pr(OCMe₂CH₂Me)₃.

31. A method comprising:
forming a memory array in a substrate including:
forming a dielectric layer containing nanolaminate interleaved dielectric layers of praseodymium oxide and zirconium oxide layers in an integrated circuit including forming the praseodymium oxide and zirconium oxide layers by at least one of an atomic layer deposition and a metallo-organic chemical vapor deposition; and
depositing a conductive layer contacting the dielectric layer; and
forming an address decoder in the substrate, the address decoder coupled to the memory array.

32. The method of claim 31, wherein the method is a method of forming a flash memory device, and forming the dielectric layer includes forming the dielectric layer as an inter-gate insulator having the conductive layer as a gate of a transistor in the flash memory device.

33. The method of claim 31, wherein the method is a method of forming a memory device including forming the conductive layer as an electrode of a capacitor and forming the dielectric layer as a dielectric of the capacitor in the memory device.

34. The method of claim 31, wherein the method further includes:
forming metallization lines in the memory array; and
annealing the device in a H₂ ambient after forming the metallization lines.

35. The method of claim 31, wherein the dielectric layer is formed using a precursor comprising a formula Pr(OCMe₂CH₂Me)₃, and a second precursor comprising a formula Zr(OCMe₂CH₂Me)₄.

36. The method of claim 31, wherein depositing a conductive layer includes depositing by sputtering.

37. The method of claim 31, wherein a first one of the interleaved dielectric layers comprises praseodymium oxide.

38. The method of claim 31, wherein the dielectric layer is formed at a temperature of less than 350° C.

39. A method comprising:
providing a controller;
coupling an integrated circuit to the controller, wherein the integrated circuit includes a dielectric layer contacting a conductive layer, the dielectric comprising a nanolaminate of interleaved dielectric layers of praseodymium oxide and zirconium oxide layers, wherein forming the dielectric layer contacting the conductive layer includes:
forming the nanolaminate dielectric layer by at least one of and atomic layer deposition and a metallo-organic chemical vapor deposition; and
depositing the conductive layer such that the conductive layer contacts the dielectric layer.

40. The method of claim 39, wherein coupling an integrated circuit to the controller includes coupling a memory device formed as the integrated circuit.

41. The method of claim 39, wherein providing a controller includes providing a processor.

42. The method of claim 39, wherein coupling an integrated circuit to the controller includes coupling a mixed signal integrated circuit formed as the integrated circuit having the dielectric layer contacting the conductive layer.

43. The method of claim 39, wherein the method is a method of forming an information handling system.

44. An electronic device comprising:
an amorphous dielectric layer containing an atomic layer deposited nanolaminate of interleaved dielectric layers of praseodymium oxide and zirconium oxide layers in an integrated circuit; and
a conductive layer contacting the dielectric layer.

45. The electronic device of claim 44, wherein the electronic device includes a memory having the nanolaminate as a gate insulator in a transistor device.

46. The electronic device of claim 45, wherein the gate insulator in the memory device is an inter-gate insulator in a flash memory device

47. The electronic device of claim 44, wherein the electronic device includes a transistor in the integrated circuit, the transistor having the dielectric layer as a gate insulator and the conductive layer as a gate in the transistor.

48. The electronic device of claim 44, wherein the electronic device includes a CMOS transistor in the integrated circuit, the CMOS transistor having the dielectric layer as a gate insulator and the conductive layer as a gate.

49. The electronic device of claim 44, wherein the electronic device includes a capacitor having the dielectric layer as a dielectric material between two electrodes in the capacitor, and the conductive layer as at least one of the two electrodes.

50. A system comprising:
a controller;
an electronic device coupled to the controller, wherein the electronic device includes:
a dielectric layer comprising an atomic layer deposited nanolaminate of interleaved dielectric layers of praseodymium oxide and zirconium oxide in an integrated circuit; and
a conductive layer contacting the dielectric layer.

51. The system of claim 50, wherein the electronic device includes a memory.
